(19) United States
(12) Patent Application Publication
(10) Pub. No.: US 2026/0033389 A1
(43) Pub. Date: Jan. 29, 2026

(54) SEMICONDUCTOR PACKAGE

(71) Applicant: SAMSUNG ELECTRONICS CO., LTD., SUWON-SI (KR)

(72) Inventor: Hansae Lim, Suwon-si (KR)

(21) Appl. No.: 19/020,230

(22) Filed: Jan. 14, 2025

(30) Foreign Application Priority Data
Jul. 24, 2024 (KR) 10-2024-0097721

(51) Int. Cl. H01L 25/07; H01L 23/00; H01L 23/538

(52) U.S. Cl. CPC H01L 25/071; H01L 23/5386; H01L 24/16; H01L 24/32; H01L 24/48; H01L 24/73; H01L 2224/16227; H01L 2224/32145; H01L 2224/48227; H01L 2224/73253; H01L 2224/73265

(57) ABSTRACT

A semiconductor package includes a package substrate having connection terminals. The connection terminals include first to fourth DQ terminals, and first and second CA terminals. A first chip stack has a first semiconductor chip flip-chip-mounted and connected to the first DQ terminals, and a fourth semiconductor chip on the first semiconductor chip wire-bonded to be connected to the fourth DQ terminals. A second chip stack has a second semiconductor chip flip-chip-mounted and connected to the second DQ terminals, and a third semiconductor chip on the second semiconductor chip wire-bonded and connected to the third DQ terminals. The first and third semiconductor chips are commonly connected to the first CA terminals, and the second and the fourth semiconductor chips are commonly connected to the second CA terminals.

### CROSS-REFERENCE TO RELATED APPLICATION(S)

This application claims priority under 35 U.S.C. § 119 to Korean Patent Application No. 10-2024-0097721, filed on Jul. 24, 2024 in the Korean Intellectual Property Office, the disclosure of which is herein incorporated by reference in its entirety.

### TECHNICAL FIELD

The present inventive concept relates to a semiconductor package, and more particularly, to a semiconductor package and a memory module including the same.

### DISCUSSION OF THE RELATED ART

With the rapid advancements in the electronics industry and increasing user demand, electronic devices are becoming progressively smaller and lighter. To align with this trend, semiconductor packages used in these devices are also being designed to be more compact and lightweight. Additionally, these semiconductor packages must ensure high reliability, superior performance, and increased capacity to meet the evolving needs of modern devices.

In semiconductor packages, the semiconductor chip is typically mounted on a printed circuit board (PCB) using either a wire bonding structure or a flip-chip structure. The PCB is then mounted onto a board substrate through connection terminals, such as solder balls. These connection terminals are often arranged in a two-dimensional grid pattern on a lower surface of the PCB.

### SUMMARY

A semiconductor package includes a package substrate. Connection terminals are disposed on a lower surface of the package substrate. The connection terminals include data signal (DQ) terminals, including first to fourth channels, and command and address signal (CA) terminals, including a first common channel and a second common channel. A first chip stack has a first semiconductor chip flip-chip-mounted on the package substrate and electrically connected to the DQ terminals of the first channel and a fourth semiconductor chip disposed on the first semiconductor chip and wire-bonded to be electrically connected to the DQ terminals of the fourth channel. A second chip stack has a second semiconductor chip flip-chip-mounted to be connected to the DQ terminals of the second channel, and a third semiconductor chip disposed on the second semiconductor chip and wire-bonded to be connected to the DQ terminals of the third channel. The first semiconductor chip and the third semiconductor chip are commonly connected to the CA terminals of the first common channel, and the second semiconductor chip and the fourth semiconductor chip are commonly connected to the CA terminals of the second common channel.

A semiconductor package includes a package substrate having a first channel region and a third channel region, adjacent to a first side, a second channel region and a fourth channel region adjacent to a second side opposite to the first side, and a first common channel region and a second common channel region, respectively disposed between the first and third channel regions and between the second and fourth channel regions. Connection terminals are disposed on a lower surface of the package substrate. The connection terminals include first to fourth data signal (DQ) terminals respectively disposed in the first to fourth channel regions, and first and second command and address signal (CA) terminals respectively disposed in the first and second common channel regions. A first chip stack has a first semiconductor chip flip-chip-mounted on the package substrate and electrically connected to the first DQ terminals, and a fourth semiconductor chip disposed on the first semiconductor chip and wire-bonded to be electrically connected to the fourth DQ terminals. A second chip stack has a second semiconductor chip flip-chip-mounted on the package substrate and electrically connected to the second DQ terminals, and a third semiconductor chip disposed on the second semiconductor chip and wire-bonded to be electrically connected to the third DQ terminals. The first to fourth semiconductor chips respectively include first to fourth CA chip pads. The first and third CA chip pads are arranged identically in a first order along facing sides of the first and third semiconductor chips, respectively, and the second and fourth CA chip pads are arranged identically in a second order, opposite to the first order, along facing sides of the second and fourth semiconductor chips, respectively. The first and third CA chip pads are commonly connected to the first CA terminals, and the second and fourth CA chip pads are commonly connected to the second CA terminals.

A semiconductor package includes a package substrate having a first channel region and a third channel region, adjacent to a first side, a second channel region and a fourth channel region adjacent to a second side opposite to the first side, and a first common channel region and a second common channel region, respectively disposed between the first and third channel regions and between the second and fourth channel regions. Connection terminals are disposed on a lower surface of the package substrate. The connection terminals include first to fourth data signal (DQ) terminals respectively disposed in the first to fourth channel regions, and first and second command and address signal (CA) terminals respectively disposed in the first and second common channel regions. A first chip stack has a first semiconductor chip flip-chip-mounted on partial areas of the first and third channel regions of the package substrate and electrically connected to the first DQ terminals, and a fourth semiconductor chip disposed on the first semiconductor chip and wire-bonded to be electrically connected to the fourth DQ terminals. A second chip stack has a second semiconductor chip flip-chip-mounted on partial areas of the second and fourth channel regions of the package substrate and electrically connected to the second DQ terminals, and a third semiconductor chip disposed on the second semiconductor chip and wire-bonded to be electrically connected to the third DQ terminals. The first semiconductor chip and the third semiconductor chip are commonly connected to the first CA terminals, and the second semiconductor chip and the fourth semiconductor chip are commonly connected to the second CA terminals.

### BRIEF DESCRIPTION OF DRAWINGS

The above and other aspects and features of the present inventive concept will be more clearly understood from the following detailed description, taken in conjunction with the accompanying drawings, in which:

FIG. 1 is a cross-sectional view illustrating a semiconductor package according to an embodiment.

FIG. 2 is a plan view illustrating a package substrate employed in the semiconductor package of FIG. 1.

FIGS. 3A and 3B are plan views illustrating an arrangement of semiconductor chips on each layer level of the semiconductor package of FIG. 1.

FIGS. 4A and 4B are plan views illustrating an arrangement and connection relationship of semiconductor chips of the same channels of the semiconductor package of FIG. 1.

FIG. 5A is a cross-sectional view illustrating a semiconductor package according to a first comparative example (wire bonding chip stack).

FIG. 5B is a plan view illustrating the semiconductor package according to the first comparative example of FIG. 5A.

FIG. 6A is a cross-sectional view illustrating a semiconductor package according to a second comparative example (same channel chip stack).

FIG. 6B is a plan view illustrating the semiconductor package according to the second comparative example of FIG. 6A.FIG. 7A is a plan view illustrating a semiconductor module according to an embodiment, and FIG. 7B is a plan view of a portion of FIG. 7A, illustrating a front surface of the semiconductor package.

FIG. 8 is a cross-sectional view illustrating a semiconductor package according to an embodiment.

FIG. 9 is a plan view illustrating a package substrate employed in the semiconductor package of FIG. 8.

FIGS. 10A and 10B are plan views illustrating arrangements and connection relationships of semiconductor chips of the same channels of the semiconductor package of FIG. 8.

### DETAILED DESCRIPTION

Hereinafter, various embodiments will be described in more detail with reference to the attached drawings.

Embodiments of the present disclosure relate to novel semiconductor packaging designs and their associated methodologies. For example, embodiments of the present disclosure may utilize an innovative semiconductor chip stack design that incorporates a first chip stack with a flip-chip-mounted lower semiconductor chip and a wire-bonded upper semiconductor chip. A similar structure may then be implemented for the second chip stack.

This stacking method increases reliability and performance while minimizing the complexity of wiring circuits.

Moreover, example embodiments of the present disclosure may provide optimized signal routing in which command and address signal (CA) pads for chips sharing a channel are aligned in the same order. This simplifies wiring, reduces the number of substrate layers, and maintains consistent routing distances.

Data signal (DQ) terminals may be organized in distinct channel regions, ensuring equal connection distances for optimized signal integrity.

Example embodiments of the present disclosure may also provide enhanced heat dissipation by distributing chips sharing command and address signals across different stacks, allowing for better thermal management by avoiding heat concentration within a single stack.

The arrangement of chip pads and bonding structures may be symmetrically designed (e.g., may have 180° rotational symmetry), ensuring equal path lengths for signals and facilitating simpler manufacturing and debugging processes.

By integrating multiple semiconductor chips (e.g., DRAM chips) within a single package, the design supports higher capacitance while meeting the industry demands for smaller, lighter devices.

The alignment of CA pads and the distribution of DQ terminals may allow for reduced layers in the substrate wiring, cutting manufacturing costs and increasing scalability.

Moreover, the package structure may adhere to various industry standards such as the JEDEC (formerly the Joint Electron Device Engineering Council) Ball Map, ensuring compatibility with existing systems.

These designs may accordingly provide simplified wiring complexity, better thermal management, and greater device miniaturization, ultimately enhancing the performance and reliability of electronic devices.

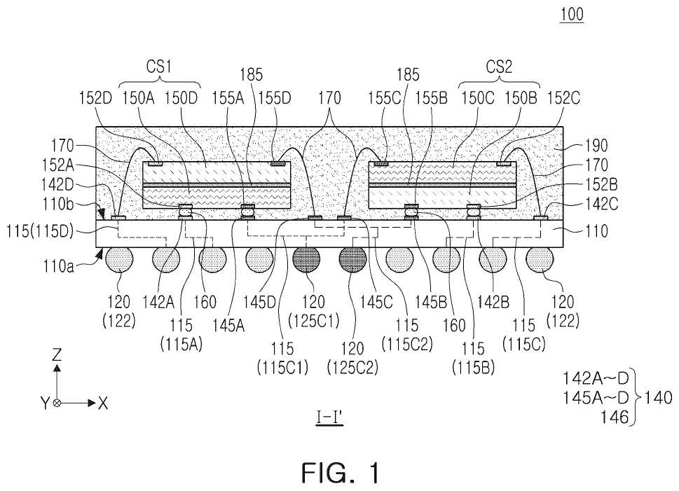

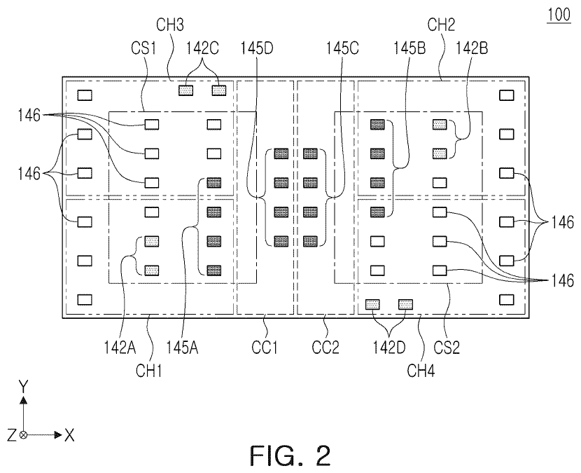

FIG. 1 is a cross-sectional view illustrating a semiconductor package according to an embodiment, and FIG. 2 is a plan view illustrating a package substrate employed in the semiconductor package of FIG. 1.

Referring to FIGS. 1 and 2, a semiconductor package 100, according to the present embodiment, may include a package substrate 110, a first chip stack CS1 including a first semiconductor chip 150A and a fourth semiconductor chip 150D disposed on one region of the package substrate 110, a second chip stack CS2 including a second semiconductor chip 150B and a third semiconductor chip 150C disposed on another region of the package substrate 110, and a mold film 190 covering the first and second chip stacks CS1 and CS2 on the package substrate 110.

As illustrated in FIG. 1, the first chip stack CSI and the second chip stack CS2 may be mounted together on a single package substrate 110. The first chip stack CS1 and the second chip stack CS2 may be disposed in a second direction Y on one package substrate 110.

The first to fourth semiconductor chips 150A, 150B, 150C, and 150D may include a memory chip having the same physical size and/or the same storage capacity, respectively. The memory chip may be provided in a form of a bare semiconductor die. For example, the memory chip may be a DRAM chip. In the present embodiment, each of the first and second semiconductor chips 150A and 150B may have a flip-chip bonding structure having a lower surface having chip pads (152A and 155A, and 152B and 155B) arranged identically to each other, and may be provided as a lower chip in each stack structure. Each of the third and fourth semiconductor chips 150C and 150D may have a wire bonding structure having an upper surface having chip pads (152C and 155C, and 152D and 155D) arranged identically to each other, and may be provided as an upper chip in each stack structure.

Referring to FIG. 1, the first chip stack CSI may include the first semiconductor chip 150A flip-chip bonded to the package substrate 110, and the fourth semiconductor chip 150D disposed on the first semiconductor chip 150A and wire-bonded to the package substrate 110. Similarly, the second chip stack CS2 may include the second semiconductor chip 150B flip-chip bonded to the package substrate 110, and the third semiconductor chip 150C disposed on the second semiconductor chip 150B and wire-bonded to the package substrate 110. In this case, inter-chip bonding layers 185 may be disposed between the first and fourth semiconductor chips 150A and 150D and between the second and third semiconductor chips 150B and 150C, respectively.

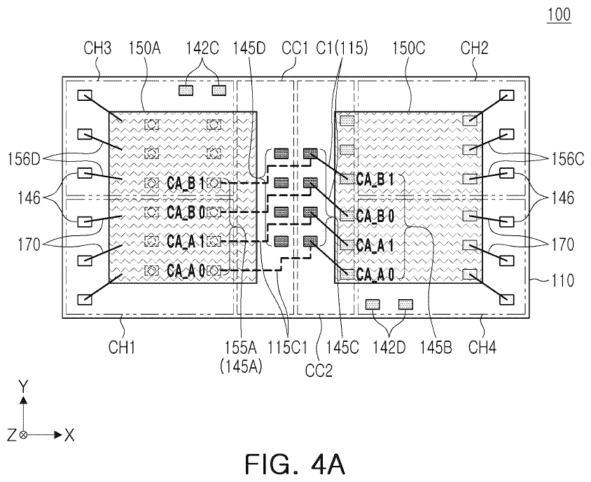

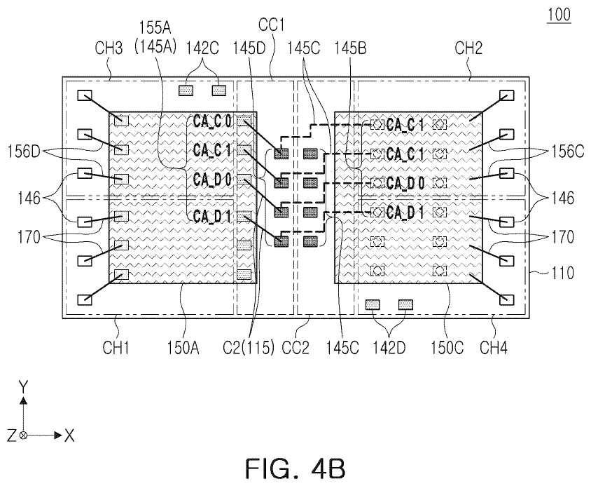

In the present embodiment, the first to fourth semiconductor chips 150A, 150B, 150C, and 150D may be connected to data signals (DQ) of a unique channel, respectively. In addition, the first semiconductor chip 150A of the first chip stack CSI may share a command/address signal (also referred to as a “CA signal of a first common channel”) with the third semiconductor chip 150C of the second chip stack CS2, and similarly, the second semiconductor chip 150B of the second chip stack CS2 may share a command/address signal (also referred to as a “CA signal of a second common channel”) with the fourth semiconductor chip 150D of the first chip stack CS1. This will be described in detail later with reference to FIGS. 4A and 4B.

The package substrate 110 may be a printed circuit board (PCB) having a lower surface 110a and an upper surface 110b opposite thereto. A plurality of connection terminals 120 may be disposed on the lower surface 110a of the package substrate 110, and a plurality of connection pads 140 may be disposed on the upper surface 110b of the package substrate 110. The plurality of connection pads 140 may be respectively connected to the plurality of connection terminals 120 by wiring circuits 115 of the package substrate 110, and may be respectively disposed in desired bonding regions for the first to fourth semiconductor chips 150A, 150B, 150C, and 150D. The wiring circuits 115 may include wiring patterns on each insulating layer of the package substrate 110, and vias connecting the wiring patterns.

The plurality of connection terminals 120 may be disposed in a two-dimensional array structure in a first direction X and the second direction Y that is perpendicular to the first direction X, on the lower surface 110a of the package substrate 110. The plurality of connection terminals 120 may be mounted on a plurality of ball lands on the lower surface 110a of the package substrate 110, respectively. For example, the plurality of connection terminals 120 may include solder balls. The plurality of connection terminals 120 may be provided as external contact points for connection with an external device (see 300 of FIG. 7A).

The plurality of connection terminals 120 may be disposed to provide a path of a signal determined according to a predetermined standard (e.g., JEDEC Ball Map standard) from an external device. The external device may control data reading from the first to fourth semiconductor chips 150A, 150B, 150C, and 150D, and data writing to the first to fourth semiconductor chips 150A, 150B, 150C, and 150D through the plurality of connection terminals 120. In the present specification, the data signals (DQ) may include data signals such as DQ, DQS, or DQSB, and a control signal may be referred to as a “command and address signal (CA),” other than the data signals. For example, the command and address signal (CA) may include CMD, ADDR, CTRL, or the like.

As described above, the data signals (DQ) may be transmitted to each of the first to fourth semiconductor chips 150A, 150B, 150C, and 150D by being divided into four channels, and as illustrated in FIG. 2, an arrangement region of DQ terminals 122 related to the data signals (“DQ1, DQ2, DQ3, and DQ4” of FIG. 7A) of each of the channels may be divided into four channel regions CH1, CH2, CH3, and CH4 in a planar manner. First to fourth channel regions CH1, CH2, CH3, and CH4 may be provided as a transmission path of the data signals (“DQ1, DQ2, DQ3, and DQ4” of FIG. 7A) of first to fourth channels provided to the first to fourth semiconductor chips 150A, 150B, 150C, and 150D, respectively.

Referring to FIG. 2, among two sides facing in the first direction X, the first and third channel regions CH1 and CH3 may be adjacent to one side, and the second and fourth channel regions CH2 and CH4 may be adjacent to the other side. The first chip stack CS1 may be disposed on partial areas of the first and third channel regions CH1 and CH3, and the second chip stack CS2 may be disposed on partial areas of the second and fourth channel regions CH2 and CH4. In the present embodiment, the first and second channel regions CH1 and CH2 may be disposed in a first diagonal direction, and the third and fourth channel regions CH3 and CH4 may be disposed in a second diagonal direction, intersecting the first diagonal direction.

As described above, the command/address signal (CA) may be transmitted by being divided into a first common channel for the first and third semiconductor chips 150A and 150C and a second common channel for the second and fourth semiconductor chips 150B and 150D, and as illustrated in FIG. 2, an arrangement region of CA terminals 125C1 and 125C2 related to command/address signals (e.g., “CA1 and CA2” of FIG. 7A) of each of the common channels may be divided into first and second common channel regions CC1 and CC2 in a planar manner. The first and second common channel regions CC1 and CC2 may be provided as a transmission path of the command/address signals (e.g., “CA1 and CA2” in FIG. 7A) of the first to fourth common channels, which may be respectively provided to the first and third semiconductor chips 150A and 150C and the second and fourth semiconductor chips 150B and 150D.

Referring to FIG. 2, the first and second common channel regions CC1 and CC2 may be disposed between the first and third channel regions CH1 and CH3 adjacent to the one side and the second and fourth channel regions CH2 and CH4 adjacent to the other side. In the present embodiment, the first and second common channel regions CC1 and CC2 may extend in the second direction Y, respectively, and may be disposed side by side in the first direction X.

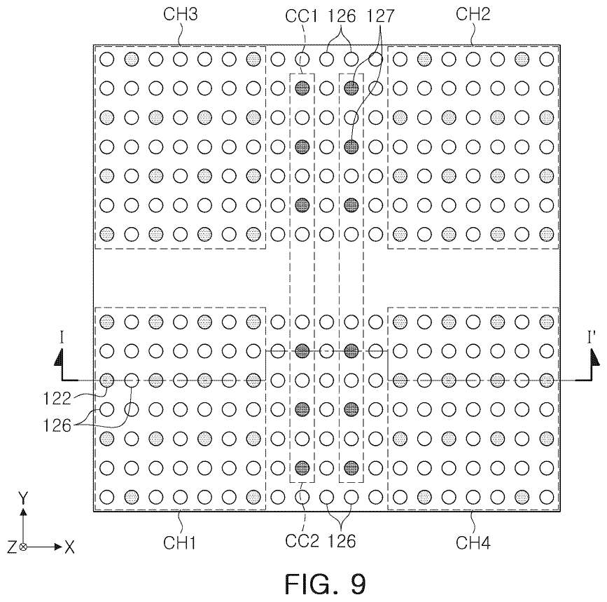

In addition, the plurality of connection terminals 120 may further include power/ground terminals 126 related to power supply for the first to fourth semiconductor chips 150A, 150B, 150C, and 150D. For example, the power/ground terminals 126 may include power supply terminals (e.g., VCC, VDD, and VPP) and ground terminals (e.g., VSS). The power/ground terminals 126 may be distributed and disposed in each channel region CH1, CH2, CH3, and CH4 and the common channel region CC1 and CC2. For example, the power supply terminals and the connection terminals may be disposed between DQ terminals 122 or between CA terminals 125 (see FIG. 9).

According to the present embodiment, chip stacks CS1 and CS2 having lower chips of a flip-chip bonding structure and upper chips of a wire bonding structure may be configured, and semiconductor chips (150A and 150C, and 150B and 150D) sharing a command/address signal (CA) may be disposed in a staggered manner on different chip stacks CS1 and CS2, thereby allowing connection pads 140 to be connected to each of the semiconductor chips 150A, 150B, 150C, and 150D to be disposed in upper surface regions overlapping or adjacent to related channel regions CH1, CH2, CH3, and CH4 and related common channel regions CC1 and CC2, and furthermore, securing symmetry (e.g., 180° rotational symmetry) of arrangement of the connection pads 140 and connection with a chip. Therefore, the wiring circuits 115 of the package substrate 110 may be kept relatively simple (e.g., the number of layers of the wiring pattern may be reduced), and routing distances between the semiconductor chips (150A, 150B and 150C, 150D) and the connection terminals 120, corresponding thereto, may be maintained constant.

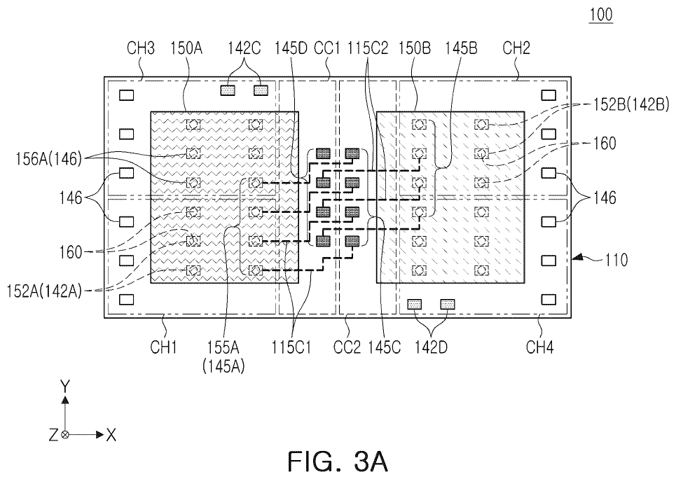

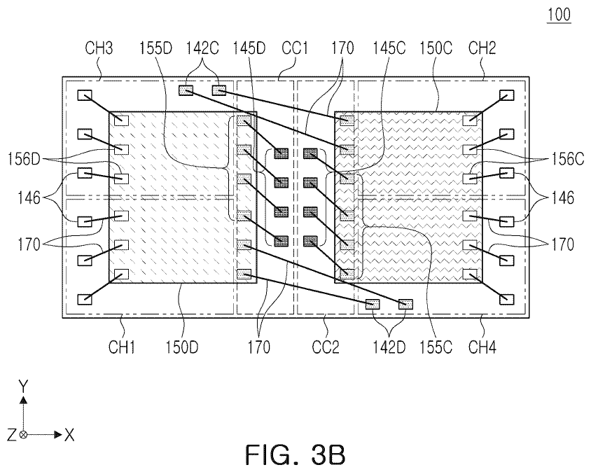

Hereinafter, bonding of the first and second chip stacks CS1 and CS2 and the connection terminals 120 (e.g., the connection pads 140) employed in the present embodiment will be described in more detail with reference to FIGS. 3A and 3B.

FIG. 3A is a plan view illustrating arrangement of the first and second semiconductor chips 150A and 150B disposed on a first layer level of the semiconductor package of FIG. 1, and FIG. 3B is a plan view illustrating arrangement of the third and fourth semiconductor chips 150C and 150D disposed on a second layer level of the semiconductor package of FIG. 1.

Referring to FIG. 3A, each of the first and second semiconductor chips 150A and 150B may have the same flip-chip bonding structure, as described above. In the present embodiment, the chip pads of the first and second semiconductor chips 150A and 150B may be disposed in two rows that are located relatively inwardly in the longitudinal direction Y on a lower surface thereof.

The present inventive concept is not necessarily limited thereto, and arrangement of the chip pads may be variously changed. In the present embodiment, the chip pads of the first semiconductor chip 150A may include first DQ chip pads 152A, first CA chip pads 155A, and first power/ground chip pads 156A. Similar to the first semiconductor chip 150A, the chip pads of the second semiconductor chips 150B may include second DQ chip pads 152B, second CA chip pads 155B, and second power/ground chip pads 156B.

The plurality of connection pads 140 respectively connected to the plurality of connection terminals 120 may be disposed on the package substrate 110. The plurality of connection pads 140 may include first to fourth DQ connection pads 142A, 142B, 142C, and 142D respectively connected to DQ terminals 122A, 122B, 122C, and 122D of the first to fourth channels, first and second CA connection pads 145A and 145B respectively connected to CA terminals 125A and 125B of the first and second common channels, and power/ground pads 146 respectively connected to the power/ground terminals 126.

In the present embodiment, the first to fourth DQ connection pads 142A, 142B, 142C, and 142D may be respectively located on the first to fourth channel regions CH1, CH2, CH3, and CH4. In particular, the first DQ connection pads 142A may be respectively located in a mounting region of the first semiconductor chip 150A, and may be respectively connected to the first DQ chip pads 152A. Similarly, the second DQ connection pads 142B may be respectively located in a mounting region of the second semiconductor chip 150B, and may be respectively connected to the second DQ chip pads 152B.

In addition, first CA terminals 125C1 may be commonly connected to the first CA connection pads 145A and the third CA connection pads 145C by a wiring circuit 115C1, respectively. The first CA connection pads 145A may be flip-chip bonded to the mounting region of the first semiconductor chip 150A. In the present embodiment, the first CA connection pads 145A may be disposed across the first and third channel regions CH1 and CH3. In addition, the third CA connection pads 145C may be adjacent to the second semiconductor chip 150B in a region between the first and second semiconductor chips 150A and 150B.

Similarly, second CA terminals 125C2 may be commonly connected to the second CA connection pads 145B and the fourth CA connection pads 145D by a wiring circuit 115C2, respectively. The second CA connection pads 145B may be flip-chip bonded in a region in which the second semiconductor chip 150B is mounted. In the present embodiment, the second CA connection pads 145B may be disposed across the second and fourth channel regions CH2 and CH4. In addition, the fourth CA connection pads 145D may be adjacent to the first semiconductor chip 150A in a region between the first and second semiconductor chips 150A and 150B.

The first and second CA connection pads 145A and 145B may be located in the mounting regions of the first and second semiconductor chips 150A and 150B, respectively, and may be connected to the first and second CA chip pads 155A and 155B, respectively. In the present embodiment, the power/ground connection pads 146 may be located entirely over the upper surface of the package substrate 110, e.g., the first to fourth channel regions CH1, CH2, CH3, and CH4, respectively. Some of the power/ground connection pads 146 may be respectively located in the mounting regions of the first and second semiconductor chips 150A and 150B, and may be respectively connected to the first and second power/ground chip pads 156A and 156B.

The chip pads of the first and second semiconductor chips 150A and 150B to be flip-chip bonded may be connected to the first and second DQ connection pads 142A and 142B, the first and second CA connection pads 145A and 145B, and some of the power/ground connection pads 146 by a conductive bump 160 such as a micro bump.

Referring to FIG. 3B, each of the fourth and third semiconductor chips 150D and 150C may have the same wire bonding structure, as described above, and may be disposed on the first and second semiconductor chips 150A and 150B, respectively. In the present embodiment, the chip pads of the third and fourth semiconductor chips 150C and 150D may be disposed in two rows adjacent to each side in the longitudinal direction Y on an upper surface thereof. The present inventive concept is not necessarily limited thereto, and arrangement of the chip pads may be variously changed.

In the present embodiment, the chip pads of the third semiconductor chips 150C may include third DQ chip pads 152C, third CA chip pads 155C, and third power/ground chip pads 156C. Similar to the third semiconductor chip 150C, the chip pads of the fourth semiconductor chip 150D may include fourth DQ chip pads 152D, fourth CA chip pads 155D, and fourth power/ground chip pads 156D.

In the present embodiment, the third and fourth DQ connection pads 142C and 142D may be located on the third and fourth channel regions CH3 and CH4, respectively. The third DQ connection pads 142C may be located outside of a mounting region of the third semiconductor chip 150C, and may be connected to the third DQ chip pads 152C by a wire 170, respectively. Similarly, the fourth DQ connection pads 142D may be located outside of a mounting region of the fourth semiconductor chip 150D, respectively, and may be connected to the fourth DQ chip pads 152D by a wire 170, respectively. Arrangement of each of the pads and a wire connection form may have 180° rotational symmetry.

In addition, the third CA connection pads 145C may be adjacent to the third semiconductor chip 150C in a region between the first and second semiconductor chips 150A and 150B. The third CA connection pads 145C may be connected to the third CA chip pads 155C by a wire 170, respectively. As described above, a CA signal CA1 of the first common channel provided to the first CA terminals 125C1 may be shared by the first and third semiconductor chips 150A and 150C by the wiring circuit 115C1.

Similarly, the fourth CA connection pads 145D may be adjacent to the fourth semiconductor chip 150D in a region between the first and second semiconductor chips 150A and 150B. The fourth CA connection pads 145D may be connected to the third CA chip pads 155C by a wire 170, respectively. As described above, a CA signal CA2 of the second common channel provided to the second CA terminals 125C2 may be shared by the second and fourth semiconductor chips 150B and 150D by the wiring circuit 115C1.

In the present embodiment, another portion of the power/ground connection pads 146 may be disposed outside of the package substrate, particularly adjacent to both sides adjacent to the third semiconductor chip 150C and the fourth semiconductor chip 150D, and the power/ground connection pads 146 located on each of the two sides may be connected to the third power/ground chip pads 156C and the fourth power/ground chip pads 156D by the wires 170, respectively.

FIGS. 4A and 4B are plan views illustrating arrangement and connection relationship of semiconductor chips of the same channels of the semiconductor package of FIG. 1.

In the present embodiment, the first semiconductor chip 150A may share the CA signal CA1 of the first common channel with the third semiconductor chip 150C, and the second semiconductor chip 150B may share the CA signal CA2 of the second common channel with the fourth semiconductor chip 150D.

Referring to FIG. 4A, the first and third semiconductor chips 150A and 150C may include four first and third CA chip pads 155A and 155C, respectively. Each of the first and third CA chip pads 155A and 155C may be used as a unique pad depending on an input CA signal (e.g., chip select signal, clock enable signal, and termination control signal). Therefore, depending on a physical order of the CA chip pads, a wiring circuit for providing a CA signal unique to each of the CA chip pads may be changed.

In the present embodiment, since the first semiconductor chip 150A includes the first CA chip pads 155A disposed in a first order (A0-A1-B0-B1) along one side in the second direction Y, and the third semiconductor chip 150C has a wire bonding structure, even when it is inverted in a face-up manner, the third semiconductor chip 150C may be disposed in another chip stack facing the one side of the first semiconductor chip 150A, such that the third CA chip pads 155C may also be disposed in the first order (A0-A1-B0-B1), identical to that of the first CA chip pads 155A, on the side facing each other. In this same order of arrangement, the first CA chip pads 155A of the first semiconductor chip 150A may be connected to the third CA connection pads 145C in parallel by the wiring circuit 115C1, respectively, and the third CA chip pads 155C of the third semiconductor chip 150C may be connected to the third CA connection pads 145A in parallel by the wire 170. As a result, the third semiconductor chip 150C may share the CA signal CA1 of the first common channel with the first semiconductor chip 150A.

Similarly, referring to FIG. 4B, since the second semiconductor chip 150B includes the second CA chip pads 155B disposed in a second order (C0-C1-D0-D1) along one side in the first direction Y, and the fourth semiconductor chip 150D has a wire bonding structure, even when it is inverted in a face-up manner, the fourth semiconductor chip 150D may be disposed in another chip stack facing the one side of the second semiconductor chip 150B, such that the fourth CA chip pads 155D may also be disposed in the second order (C0-C1-D0-D1), identical to that of the second CA chip pads 155B, on the sides facing each other. In this same order of arrangement, the second CA chip pads 155B of the second semiconductor chip 150B may be connected in parallel to the second CA connection pads 145B that may be flip-chip bonded, respectively, by the wiring circuit 115C2, and the fourth CA chip pads 155D of the fourth semiconductor chip 150D may be connected in parallel to the fourth CA connection pads 145D by the wire 170. The fourth semiconductor chip 150D may share the CA signal CA2 of the second common channel with the second semiconductor chip 150B.

In this manner, the first semiconductor chip 150A (or the second semiconductor chip 150B) and the third semiconductor chip 150C (or the fourth semiconductor chip 150D) may be configured as the two chip stacks CS1 and CS2 with a flip-chip bonded lower chip and a wire-bonded upper chip, but by being disposed in different chip stacks CS1 and CS2, the CA chip pads of a pair of semiconductor chips (150A and 150C, and 150B and 150D) sharing a CA signal may be disposed in the same order. The CA chip pads disposed in the same order may further simplify the wiring circuits 115C1 and 115C2 commonly connected to the CA terminals of the common channel, respectively, and may reduce the number of layers of the package substrate 110.

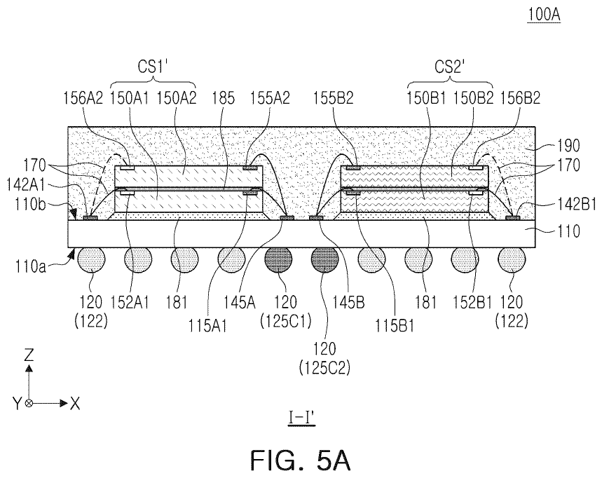

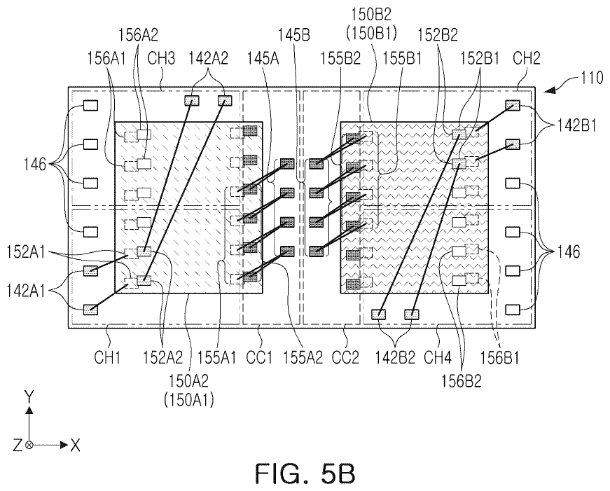

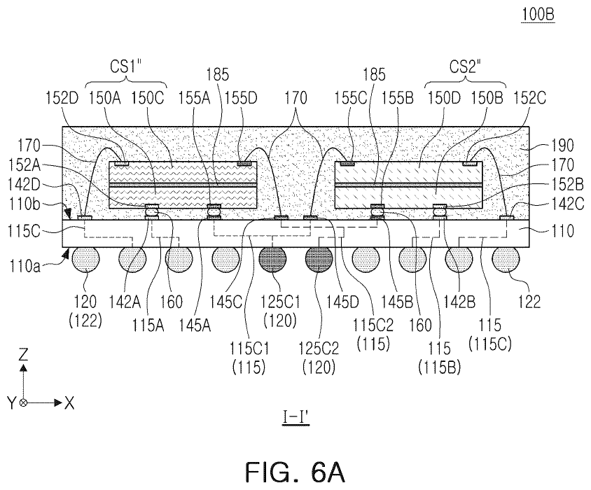

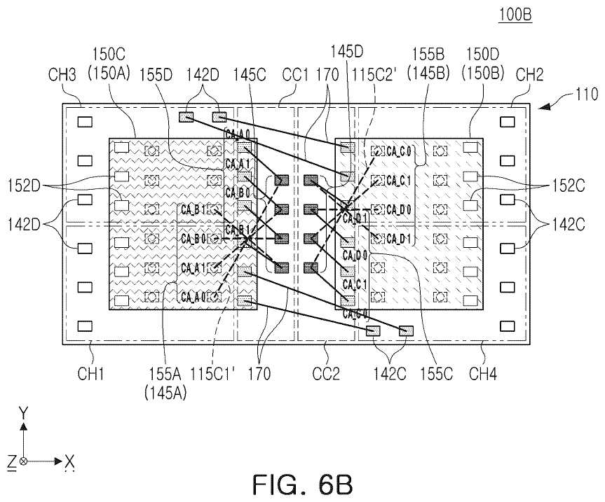

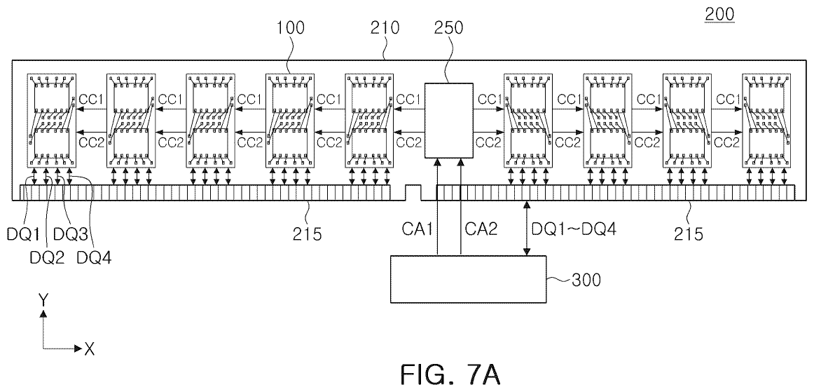

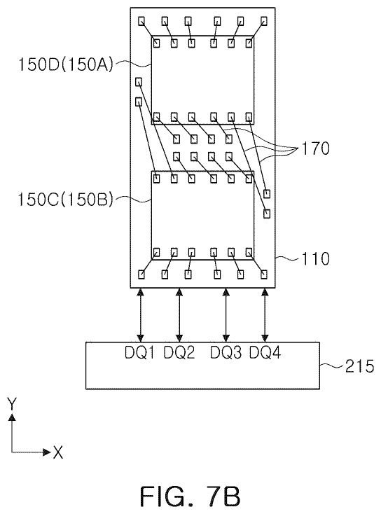

Even when the two chip stacks are formed by additionally arranging identical semiconductor chips, and when implemented as a chip stack having a structure different from that of the present embodiment (see FIGS. 5A and 5B and FIGS. 6A and 6B), problems such as a complicated wiring circuit or reduced reliability may occur. Representative semiconductor packages 100A and 100B, according to first and second comparative examples, are illustrated in FIGS. 5A and 5B and FIGS. 6A and 6B, respectively.

Referring to FIGS. 5A and 5B, a semiconductor package 100A, according to the first comparative example, may include first and second chip stacks CS1′ and CS2′ respectively formed of semiconductor chips 150A1, 150A2, 150B1, and 150B2 having a wire bonding structure.

The first chip stack CS1′ may include stacked first and second semiconductor chips 150A1 and 150A2, and the second chip stack CS2′ may include stacked first and second semiconductor chips 150B1 and 150B2. In the present embodiment, the first and third semiconductor chips 150A1 and 150B1 may be fixed to a package substrate 110 by an additional bonding layer 181. The first to fourth semiconductor chips 150A1, 150A2, 150B1, and 150B2 may each have memory chips having the same physical size and the same storage capacity, and may include chip pads disposed identically on upper surfaces thereof. The semiconductor package 100A, according to the present comparative example, may easily implement wiring connection sharing a CA signal in each of the chip stacks CS1′ and CS2′.

Referring to FIG. 5B, first CA chip pads 155A1 of the first semiconductor chip 150A1 and second CA chip pads 155A2 of the second semiconductor chip 150A2 may be disposed in the same order, and may be respectively wire bonded to first CA connection pads 145A adjacent to the first chip stack CS1′, such that the first and second semiconductor chips 150A1 and 150A2 may share a CA signal CA1 of a first common channel. Similarly, third CA chip pads 155B1 of the third semiconductor chip 150B1 and fourth CA chip pads 155B2 of the fourth semiconductor chip 150B2 may be disposed in the same order, and may be wire-bonded to second CA connection pads 145B adjacent to the second chip stack CS2′, such that the third and fourth semiconductor chips 150B1 and 150B2 may share a CA signal CA2 of a second common channel.

However, since DQ chip pads 152A1, 152A2, 152B1, and 152B2 are disposed in the same region of each of the semiconductor chips 150A1, 150A2, 150B1, and 150B2, there may be a problem that a large difference occurs in a routing path for a DQ signal.

Referring to FIG. 5B, the first and second semiconductor chips 150A1 and 150A2 may include the DQ chip pads 152A1 and 152A2 located at one side of the same side. The DQ chip pads 152A1 of the first semiconductor chip 150A1 may be connected to DQ connection pads 142A of one channel region (CH1) by a relative short path, but the DQ chip pads 152A2 of the second semiconductor chip 150A2 may be connected to DQ connection pads 142C of a different channel region (CH3) by a relative long path. This difference in connection paths may cause a deterioration in performance of the first and second semiconductor chips 150A1 and 150A2. Routing paths for DQ signals of the third and fourth semiconductor chips 150B1 and 150B2 may also cause similar problems.

Referring to FIGS. 6A and 6B, a semiconductor package 100B, according to the second comparative example, may include a first chip stack CS1″ including a first semiconductor chip 150A and a third semiconductor chip 150C, and a second chip stack CS2″ including a second semiconductor chip 150B and a fourth semiconductor chip 150D. Similar to the semiconductor package 100 illustrated in FIG. 1, the first and second semiconductor chips 150A and 150B, which may be lower chips, may have a flip-chip bonding structure, and the third and fourth semiconductor chips 150C and 150D, which may be upper chips, may have a wire bonding structure. Unlike the previous embodiment, the semiconductor chips 150A and 150C, and 150B and 150D having the same chip stack may share a CA signal with each other.

According to the second comparative example, paths connecting first to fourth DQ chip pads 152A, 152B, 152C, and 152D to DQ connection terminals of first and fourth channels or first to fourth DQ connection pads may have arrangement similar to the connection paths of the previous embodiment (particularly, see FIG. 3B).

However, according to the second comparative example, since each of the pair of semiconductor chips 150A and 150C, and 150B and 150D to share a CA signal of the same common channel may be included in the same chip stacks CS1″ and CS2″, CA signal paths of the first to fourth semiconductor chips 150A, 150B, 150C, and 150D may be implemented in a complex manner, which may result in various problems.

For example, referring to FIG. 6B, in the present embodiment, the first semiconductor chip 150A may include first CA chip pads 155A disposed in a first order (A0-A1-B0-B1) in the second direction Y along one side. Unlike the previous embodiment (see FIG. 4A), since the third semiconductor chip 150C having a wire bonding structure may be inverted in a face-up manner in the same chip stack CS1″, third CA chip pads 155C on sides corresponding thereto may be disposed in a second order (B1-B0-A1-A0), opposite to the first order of the first CA chip pads 155A. In this arrangement of the reverse order, among first paths (e.g., wiring circuits 115C1) between first CA connection pads 145A to which the first CA chip pads 155A of the first semiconductor chip 150A are flip-chip bonded, and third CA connection pads 145C, and second paths (e.g., wires 170) between the third CA chip pads 155C of the third semiconductor chip 150C and the third CA connection pads 145C, paths of one group should be formed in the reversed order. For example, as illustrated in FIG. 6B, in a case in which the second paths, e.g., wires 170, may be connected in parallel without overlapping, in order for the first semiconductor chip 150A and the third semiconductor chip 150C to share a CA signal CA1 of the first common channel, the first paths, e.g., the wiring circuits 115C1, should be connected in the reversed order, and as a result, the wiring circuits 115C1 may be formed to intersect one another in a plan view.

Similarly, the second semiconductor chip 150B may include second CA chip pads 155B disposed in the second order (B1-B0-A1-A0) in the second direction Y along one side, and unlike the previous embodiment (see FIG. 4A), since the fourth semiconductor chip 150D having a wire bonding structure may be inverted in a face-up manner in the same chip stack CS2″, fourth CA chip pads 155D on sides corresponding thereto may be disposed in the first order (A0-A1-B0-B1), opposite to the second order of the second CA chip pads 155B. In this arrangement of the reverse order, among first paths (e.g., wiring circuit 115C2) between the first CA connection pads 145A to which the second CA chip pads 155B of the second semiconductor chip 150B are flip-chip bonded, and the third CA connection pads 145C, and second paths (e.g., wires 170) between the fourth CA chip pads 155D of the fourth semiconductor chip 150D and the fourth CA connection pads 145D, paths of one group should be formed in the reverse order. For example, as illustrated in FIG. 6B, in a case in which the second paths, e.g., the wires 170, may be connected in parallel without overlapping, in order for the second semiconductor chip 150B and the third semiconductor chip 150C to share a CA signal CA2 of the second common channel, the first paths, e.g., the wiring circuits 115C2, should be connected in the reversed order, and as a result, the wiring circuits 115C1 may be formed to intersect one another, in a plan view.

Therefore, in the semiconductor package 100B, according to the second comparative example, to implement the intersecting wiring circuit 115C1 in a package substrate, the number of layers of the package substrate 110 would have to be increased. On the other hand, in the present embodiment in which a connection structure is simplified by arranging CA elements in the same order, since the wiring circuit of the package substrate may be formed more simply, the number of layers may be reduced.

In addition, in the present embodiment, the first semiconductor chip 150A (or the second semiconductor chip 150B) and the third semiconductor chip 150C (or the fourth semiconductor chip 150D) may each be configured as the two chip stacks CS1″ and CS2″ with the flip-chip bonded lower chips and the wire-bonded upper chips, but may be disposed in the different chip stacks CS1″ and CS2″, such that even when the pair of semiconductor chips are operated in the common channel, the semiconductor chips belonging to the different chip stacks may be driven, such that heat dissipation may be more easily achieved through each of the chip stacks. In contrast, in the first and second comparative examples, since the pair of semiconductor chips operating in the common channel constitute the same stack, heat generation may be concentrated, making heat dissipation difficult, and reliability may be reduced.

FIG. 7A is a plan view illustrating a semiconductor module according to an embodiment, and FIG. 7B is a plan view of a portion of FIG. 7A, illustrating a front surface of the semiconductor package.

Referring to FIG. 7A, a semiconductor module 200A may include a module substrate 210, a plurality of semiconductor packages 100 provided on the module substrate 210, and a connector 215 provided on one edge of an upper surface of the module substrate 210. Data signals DQ1, DQ2, DQ3, and DQ4 of first to fourth channels may be transmitted between the semiconductor packages 100 and the connector 215.

The semiconductor module 200A may include a memory module such as a DRAM module. For example, the semiconductor module 200A may include a plurality of semiconductor packages 100, and each of the plurality of semiconductor packages 100 may include two or more memory chips.

The semiconductor module 200A may further include a buffer chip 250 provided on the module substrate 210. The buffer chip 250 may buffer signals provided from an external device 300, such as a memory controller, for example, a command signal CMD, an address signal ADDR, and a control signal CTRL, and may provide the signals to the semiconductor package 100. The external device 300 may control data reading from the semiconductor package 100 and data writing to the semiconductor package 100. CA signals CA1 and CA2 of first and second common channels may be transmitted from the external device 300 or the buffer chip 250 to the semiconductor package 100.

Referring to FIG. 7B, each of the plurality of semiconductor packages 100 may include a first chip stack of first and fourth semiconductor chips 150A and 150D and a second chip stack of second and third semiconductor chips 150B and 150C on a single package substrate 110, as described in FIGS. 1 to 4B. The first and second semiconductor chips 150A and 150B may be provided as lower chips, and may be flip-chip bonded to the package substrate 110. The third and fourth semiconductor chips 150C and 150D may be bonded to the package substrate 110 by wires 170.

As described in the above embodiment, paths may provide the data signals DQ1, DQ2, DQ3, and DQ4 of the first channel to the fourth channel to the first to fourth semiconductor chips 150A, 150B, 150C, and 150D, respectively. In addition, paths may share a CA signal CA1 of the first common channel between the first and third semiconductor chips 150A and 150C located in different chip stacks, and paths may share a CA signal CA2 of the second common channel between the second and fourth semiconductor chips 150B and 150D located in different chip stacks.

In an embodiment, the module substrate 210 may have a rectangular shape in which a length of the first direction X is greater than a length of the second direction Y, intersecting therewith. The semiconductor packages 100 may be spaced apart from each other in the first direction X. The buffer chip 250 may be provided in a central portion of the upper surface of the module substrate 210 or a region adjacent thereto. In addition, the connector 215 may include a plurality of pads disposed in the first direction X.

The structure implemented on the upper surface of the module substrate 210 may be implemented on a lower surface of the module substrate 210 in the same or similar manner. In some embodiments, the semiconductor module 200A may further include at least one semiconductor package provided on the lower surface of the module substrate 210, and optionally may further include a buffer chip 250.

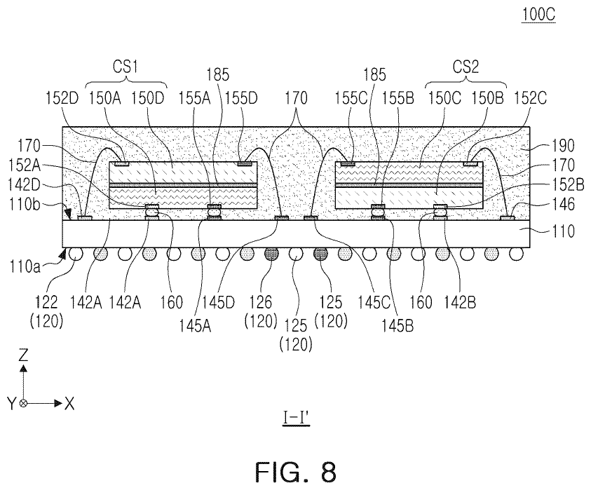

FIG. 8 is a cross-sectional view illustrating a semiconductor package according to an embodiment, and FIG. 9 is a plan view illustrating a package substrate employed in the semiconductor package of FIG. 8.

Referring to FIGS. 8 and 9, a semiconductor package 100C, according to the present embodiment, may include, similarly to the embodiments illustrated in FIGS. 1 and 2, a package substrate 110, a first chip stack CSI including a first semiconductor chip 150A and a fourth semiconductor chip 150D in one region of the package substrate 110, a second chip stack CS2 including a second semiconductor chip 150B and a third semiconductor chip 150C in another region of the package substrate 110, and a mold film 190 covering the first and second chip stacks CS1 and CS2 on the package substrate 110.

The package substrate 110 employed in the present embodiment may have arrangement of connection terminals similar to the JEDEC Ball Map standard. Referring to FIG. 9, a plurality of connection terminals 120 may be disposed on a lower surface of the package substrate 110, and the plurality of connection terminals 120 may be disposed in a two-dimensional array structure in the first direction X and the second direction Y, perpendicular to the first direction X, on a lower surface 110a of the package substrate 110. The plurality of connection terminals 120 may include DQ terminals 122 divided into first to fourth channels, CA terminals 125 divided into first and second common channels, and various power/ground terminals 126.

As illustrated in FIG. 9, an arrangement region of the DQ terminals 122 related to data signals of each channel (“DQ1, DQ2, DQ3, and DQ4” of FIG. 7A) may be divided into four channel regions CH1, CH2, CH3, and CH4 in a plan view. An arrangement region of the CA terminals 125 related to command/address signals of each common channel (“CA1 and CA2” in FIG. 7A) may be divided into two common channel regions CC1 and CC2 in a planar manner.

The first and third channel regions CH1 and CH3 may be adjacent to one side of the package substrate 110, and the second and fourth channel regions CH2 and CH4 may be adjacent to the other side, opposing the one side. First and second common channel regions may be disposed between the first and third channel regions and the second and fourth channel regions.

Referring to FIG. 9, the first chip stack CS1 may be disposed on partial areas of the first and third channel regions CH1 and CH3 and partial areas of the first common channel region CC1, and the second chip stack CS2 may be disposed on partial areas of the second and fourth channel regions CH2 and CH4 and partial areas of the second common channel region CC2. In the present embodiment, the first and second channel regions CH1 and CH2 may be disposed in a first diagonal direction, and the third and fourth channel regions CH3 and CH4 may be disposed in a second diagonal direction, intersecting the first diagonal direction.

Power/ground terminals 126 related to power supply may include, for example, various power supply terminals (e.g., VCC, VDD, and VPP) and ground terminals (e.g., VSS). The power/ground terminals 126 may be distributed to the channel regions CH1, CH2, CH3, and CH4 and the common channel regions CC1 and CC2, respectively, and the power supply terminals and the connection terminals may be disposed between the DQ terminals 122 or between the CA terminals 125.

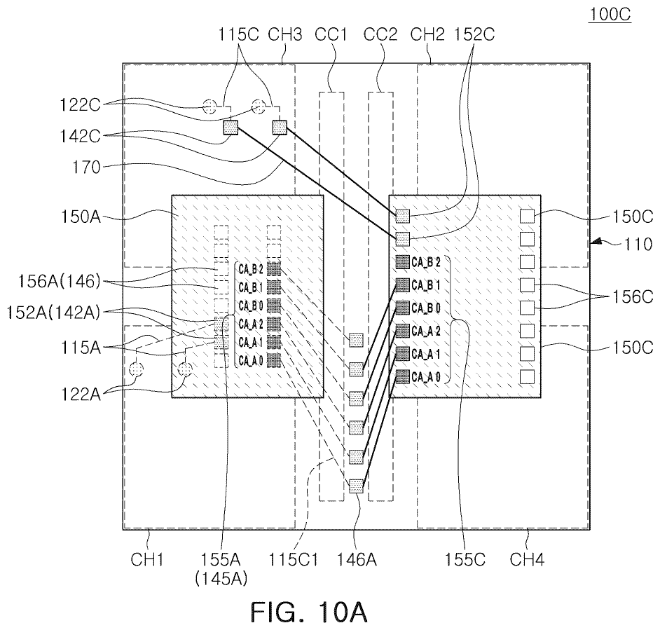

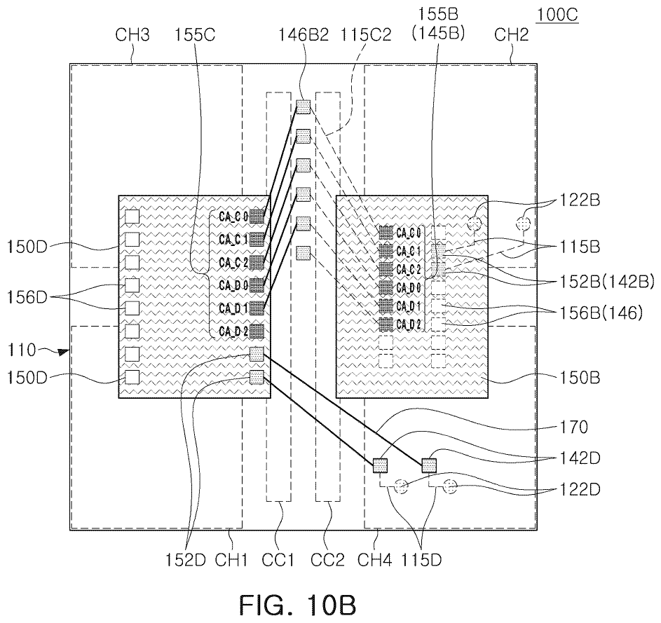

FIGS. 10A and 10B are plan views illustrating arrangement and connection relationship of semiconductor chips of the same channels of the semiconductor package of FIG. 8.

Referring to FIGS. 10A and 10B, the first to fourth semiconductor chips 150A, 150B, 150C, and 150D may be connected to DQ signals DQ1, DQ2, DQ3, and DQ4 of channels, e.g., first to fourth DQ terminals 122A, 122B, 122C, and 122D, respectively.

First, as illustrated in FIG. 10A, first DQ chip pads 152A of the first semiconductor chip 150A may be flip-chip bonded to first DQ connection pads 142A in the first channel region CH1, respectively. The first DQ connection pads 142A may be connected to the first DQ connection terminals 122A of the first channel region CHI by a wiring circuit 115A, respectively. Third DQ chip pads 152C of the third semiconductor chip 150C may be bonded to third DQ connection pads 142C on the third channel region CH3 by a wire 170, respectively. The third DQ connection pads 142C may be connected to the third DQ connection terminals 122C of the third channel region CH3 by a wiring circuit 115C.

Similarly, as illustrated in FIG. 10B, second DQ chip pads 152B of the second semiconductor chip 150B may be flip-chip bonded to second DQ connection pads 142B in the second channel region CH2, respectively. The second DQ connection pads 142B may be connected to the second DQ connection terminals 122B of the second channel region CH2 by a wiring circuit 115B, respectively. Fourth DQ chip pads 152D of the fourth semiconductor chip 150D may be bonded to fourth DQ connection pads 142D on the fourth channel region CH4 by a wire 170, respectively. The fourth DQ connection pads 142D may be connected to the fourth DQ connection terminals 122D of the fourth channel region CH4 by a wiring circuit 115D.

In some embodiments, the first and second DQ connection pads 142A and 142B may be located slightly away from the first and second channel regions CH1 and CH2, respectively, in a region in which the first and second semiconductor chips 150A and 150B are mounted. Similarly, the third and fourth DQ connection pads 142C and 142D may be located slightly away from the third and fourth channel regions CH3 and CH4, respectively.

Referring to FIG. 10A, each of the first and third semiconductor chips 150A and 150C may include six first and third CA chip pads 155A and 155C. Depending on a physical order of each of the CA chip pads, a unique CA signal may be provided.

In the present embodiment, since the first semiconductor chip 150A includes the first CA chip pads 155A disposed in a first order (A0-A1-A2-B0-B1-B2) along one side in the second direction Y, and the third semiconductor chip 150C has a wire bonding structure, even when it is inverted in a face-up manner, the third semiconductor chip 150C may be disposed in another chip stack facing the one side of the first semiconductor chip 150A. On the sides facing each other, the third CA chip pads 155C may also be disposed in the same first order (A0-A1-A2-B0-B1-B2) as the first CA chip pads 155A.

In this same order arrangement, the first CA chip pads 155A of the first semiconductor chip 150A may be connected to the third CA connection pads 145A in parallel by the wiring circuit 115C1, and the third CA chip pads 155C of the third semiconductor chip 150C may be connected to the third CA connection pads 145A in parallel by the wire 170. As a result, the third semiconductor chip 150C may share a CA signal CAI of the first common channel with the first semiconductor chip 150A.

Similarly, referring to FIG. 10B, since the second semiconductor chip 150B includes the second CA chip pads 155B disposed in a second order (D2-D1-D0-C2-C1-C0) along one side in the first direction Y, and the fourth semiconductor chip 150D has a wire bonding structure, even when it is inverted in a face-up manner, the fourth semiconductor chip 150D may be disposed in another chip stack facing the one side of the second semiconductor chip 150B, such that the fourth CA chip pads 155D may also be disposed in the second order (D2-D1-D0-C2-C1-C0), identical to that of the second CA chip pads 155B, on the sides facing each other. In this same order of arrangement, the second CA chip pads 155B of the second semiconductor chip 150B may be connected in parallel to the second CA connection pads 145B that may be flip-chip bonded, respectively, by the wiring circuit 115C2, and the fourth CA chip pads 155D of the fourth semiconductor chip 150D may be connected in parallel to the fourth CA connection pads 145D by the wire 170. The fourth semiconductor chip 150D may share a CA signal CA2 of the second common channel with the second semiconductor chip 150B.

In this manner, the first semiconductor chip 150A (or the second semiconductor chip 150B) and the third semiconductor chip 150C (or the fourth semiconductor chip 150D) may be configured as the two chip stacks CS1 and CS2 with a flip-chip bonded lower chip and a wire-bonded upper chip, but by being disposed in different chip stacks CS1 and CS2, the CA chip pads of a pair of semiconductor chips (150A and 150C, and 150B and 150D) sharing a CA signal may be disposed in the same order. The CA chip pads disposed in the same order may further simplify the wiring circuits 115C1 and 115C2 commonly connected to the CA terminals of the common channel, respectively, and may reduce the number of layers of the package substrate.

In addition, a connection structure of the first and third semiconductor chips of FIG. 10A and a connection structure of the second and fourth semiconductor chips of FIG. 10B may secure rotational symmetry of 180°. In this manner, a path length between the first semiconductor chip 150A and the connection terminals 120 may correspond to a path length between the second semiconductor chip 150B and the connection terminals 120, respectively. Similarly, a path length between the fourth semiconductor chip 150D and the connection terminals 120 may correspond to a path length between the third semiconductor chip 150C and the connection terminals 120, respectively.

As described above, since orders of command and address pads of the semiconductor chips, operating in the same channel, may be the same by arranging a flip-chip bonded lower semiconductor chip and a wire-bonded upper semiconductor chip, operating in the same channel, in different chip stacks, respectively, a related wiring structure may be kept relatively simple, and the number of layers of a package substrate may be reduced. In addition, since symmetry of arrangement of semiconductor chips (or chip stacks) may be maintained, a distance between a chip pad and a ball in each of the semiconductor chips may be maintained constant. Since semiconductor chips belonging to the different chip stacks may be driven when performing the same channel, it is also advantageous in terms of heat dissipation characteristics.

Various aspects of the present inventive concept have been described herein with reference to the figures but are not necessarily limited to the above-described contents, and may be more easily understood in the process of explaining specific embodiments.

While example embodiments have been illustrated and described above, it will be apparent to those skilled in the art that modifications and variations could be made without departing from the scope of the present disclosure.

1. A semiconductor package, comprising:
a package substrate;
connection terminals disposed on a lower surface of the package substrate, wherein the connection terminals include data signal terminals including first to fourth channels, and command and address signal terminals including a first common channel and a second common channel;
a first chip stack having a first semiconductor chip flip-chip-mounted on the package substrate and electrically connected to the data signal terminals of the first channel, and a fourth semiconductor chip disposed on the first semiconductor chip and wire-bonded to be electrically connected to the data signal terminals of the fourth channel; and
a second chip stack having a second semiconductor chip flip-chip-mounted on the package substrate and electrically connected to the data signal terminals of the second channel, and a third semiconductor chip disposed on the second semiconductor chip and wire-bonded to be electrically connected to the data signal terminals of the third channel,
wherein the first semiconductor chip and the third semiconductor chip are commonly connected to the command and address signal terminals of the first common channel, and the second semiconductor chip and the fourth semiconductor chip are commonly connected to the command and address signal terminals of the second common channel.

2. The semiconductor package of claim 1,
wherein the package substrate comprises first to fourth channel regions in which the data signal terminals of the first to fourth channels are respectively disposed,
wherein the first chip stack is disposed on partial areas of the first and third channel regions, and
wherein the second chip stack is disposed on partial areas of the second and fourth channel regions.

3. The semiconductor package of claim 2,
wherein the first semiconductor chip is flip-chip bonded to first data signal connection pads on the first channel region, and connected to the data signal terminals of the first channel through the first data signal connection pads, and
wherein the fourth semiconductor chip is wire-bonded to fourth data signal connection pads on the fourth channel region, and connected to the data signal terminals of the fourth channel through the fourth data signal connection pads.

4. The semiconductor package of claim 2,
wherein the second semiconductor chip is flip-chip bonded to second data signal connection pads on the second channel region, and connected to the data signal terminals of the second channel through the second data signal connection pads, and
wherein the third semiconductor chip is wire-bonded to third data signal connection pads on the third channel region, and connected to the data signal terminals of the third channel through the third data signal connection pads.

5. The semiconductor package of claim 2, wherein the first and second channel regions are disposed in a first diagonal direction, and the third and fourth channel regions are disposed in a second diagonal direction, intersecting the first diagonal direction.

6. The semiconductor package of claim 2,
wherein the package substrate comprises first and second common channel regions in which the command and address signal terminals of the first and second common channels are respectively disposed,
wherein the first common channel region is disposed between the first and third channel regions, and
wherein the second common channel region is disposed between the second and fourth channel regions.

7. The semiconductor package of claim 6,
wherein the first semiconductor chip comprises first command and address signal chip pads respectively connected to the command and address signal terminals of the first common channel, and the third semiconductor chip comprises third command and address signal chip pads respectively connected to the command and address signal terminals of the first common channel, and
wherein the first and third command and address signal chip pads are disposed in a same order in one direction and the first and third command and address signal chip pads are arranged adjacent to facing sides of the first and third semiconductor chips, respectively.

8. (canceled)

9. The semiconductor package of claim 6,
wherein the second semiconductor chip comprises second command and address signal chip pads respectively connected to the command and address signal terminals of the second common channel, and the fourth semiconductor chip comprises fourth command and address signal chip pads respectively connected to the command and address signal terminals of the second common channel, and
wherein the second and fourth command and address signal chip pads are disposed in a same order in one direction, and the second and fourth command and address signal pads are arranged adjacent to facing sides of the second and fourth semiconductor chips, respectively.

10. (canceled)

11. The semiconductor package of claim 1, wherein the connection terminals are arranged in a two-dimensional array in a first direction and a second direction, perpendicular to the first direction on the lower surface of the package substrate.

12. The semiconductor package of claim 11,
wherein the connection terminals further comprise power supply terminals and ground terminals, and
wherein the power supply terminals and the ground terminals are disposed between the data signal terminals of the connection terminals or between the command and address signal terminals.

13. The semiconductor package of claim 1, wherein the first to fourth semiconductor chips have a memory chip having a same physical size and a same storage capacity as one another.

14. The semiconductor package of claim 13, wherein the first and second semiconductor chips have a lower surface having chip pads arranged identically to each other, and the third and fourth semiconductor chips have an upper surface having chip pads arranged identically to each other.

15. A semiconductor package, comprising:
a package substrate having a first channel region and a third channel region, adjacent to a first side, a second channel region and a fourth channel region adjacent to a second side opposite to the first side, a first common channel region disposed between the first and third channel regions, and a second common channel region disposed between the second and fourth channel regions;
connection terminals disposed on a lower surface of the package substrate, wherein the connection terminals include first to fourth data signal terminals respectively disposed in the first to fourth channel regions, and first and second command and address signal terminals respectively disposed in the first and second common channel regions;
a first chip stack having a first semiconductor chip flip-chip-mounted on the package substrate and electrically connected to the first data signal terminals, and a fourth semiconductor chip disposed on the first semiconductor chip and wire-bonded to be electrically connected to the fourth data signal terminals; and
a second chip stack having a second semiconductor chip flip-chip-mounted on the package substrate and electrically connected to the second data signal terminals, and a third semiconductor chip disposed on the second semiconductor chip and wire-bonded to be electrically connected to the third data signal terminals,
wherein the first to fourth semiconductor chips respectively include first to fourth command and address signal chip pads,
wherein the first and third command and address signal chip pads are arranged identically in a first order along facing sides of the first and third semiconductor chips, respectively, and the second and fourth command and address signal chip pads are arranged identically in a second order, opposite to the first order, along facing sides of the second and fourth semiconductor chips, respectively, and
wherein the first and third command and address signal chip pads are commonly connected to the first command and address signal terminals, and the second and fourth command and address signal chip pads are commonly connected to the second command and address signal terminals.

16. The semiconductor package of claim 15, wherein the first and second channel regions are disposed in a first diagonal direction of the package substrate, and the third and fourth channel regions are disposed in a second diagonal direction, intersecting the first diagonal of the package substrate.

17. The semiconductor package of claim 16, wherein the first common channel region is adjacent to the first and third channel regions, and the second common channel region is adjacent to the second and fourth channel regions.

18. The semiconductor package of claim 17, wherein the first chip stack is disposed on partial areas of the first and third channel regions and some region of the first common channel region, and the second chip stack is disposed on partial areas of the second and fourth channel regions and some region of the second common channel region.

19. The semiconductor package of claim 15, wherein arrangement of the first and second chip stacks and arrangement of bonding wires of the third and fourth semiconductor chips exhibit 180° rotationally symmetry with respect to one another.

20. A semiconductor package, comprising:
a package substrate having a first channel region and a third channel region, adjacent to a first side, a second channel region and a fourth channel region adjacent to a second side opposite to the first side, a first common channel region disposed between the first and third channel regions, and a second common channel region disposed between the second and fourth channel regions;
connection terminals disposed on a lower surface of the package substrate, wherein the connection terminals include first to fourth data signal terminals respectively disposed in the first to fourth channel regions, and first and second command and address signal terminals respectively disposed in the first and second common channel regions;
a first chip stack having a first semiconductor chip flip-chip-mounted on partial areas of the first and third channel regions of the package substrate and electrically connected to the first data signal terminals, and a fourth semiconductor chip disposed on the first semiconductor chip and wire-bonded to be electrically connected to the fourth data signal terminals; and
a second chip stack having a second semiconductor chip flip-chip-mounted on partial areas of the second and fourth channel regions of the package substrate and electrically connected to the second data signal terminals, and a third semiconductor chip disposed on the second semiconductor chip and wire-bonded to be electrically connected to the third data signal terminals,
wherein the first semiconductor chip and the third semiconductor chip are commonly connected to the first command and address signal terminals, and the second semiconductor chip and the fourth semiconductor chip are commonly connected to the second command and address signal terminals.

21. The semiconductor package of claim 20,
wherein the first semiconductor chip comprises first data signal chip pads respectively connected to the first data signal terminals, and the second semiconductor chip comprises second data signal chip pads respectively connected to the second data signal terminals, and
wherein electrical connection distances between the first data signal terminals and the first data signal chip pads are equal to electrical connection distances between the second data signal terminals and the second data signal chip pads, respectively.

22. The semiconductor package of claim 20,
wherein the third semiconductor chip comprises third data signal chip pads respectively connected to the third data signal terminals, and the fourth semiconductor chip comprises fourth data signal chip pads respectively connected to the fourth data signal terminals, and
wherein electrical connection distances between the third data signal terminals and the third data signal chip pads are equal to electrical connection distances between the fourth data signal terminals and the fourth data signal chip pads, respectively.

23-24. (canceled)
